(19) United States
(12) Patent Application Publication
(10) Pub. No.: US 2002/0060637 A1
(43) Pub. Date: May 23, 2002

(54) Accuracy in local signal representation

(75) Inventors: John Byrnes, San Jose, CA (US); Matthew Cushman, Santa Clara, CA (US); Aleksandar Ignjatovic, Mountain View, CA (US)

Correspondence Address: George Wolken Jr., Skjerven Morrill MacPherson LLP, Suite 700, 25 Metro Drive, San Jose, CA, 95110, US

(73) Assignee: Kromos Technology, Inc.

(21) Appl. No.: 09/954,111

(22) Filed: Sep. 12, 2001

Related U.S. Application Data
(63) Continuation of application No. 09/614,886, filed on Jul. 9, 2000.

(51) Int. Cl. H03M 1/12

(52) U.S. Cl. 341/155

(57) ABSTRACT

The present invention relates to signal processing and, more particularly, to the use of local signal behavior parameters for the description of signals within sampling windows. Improved accuracy in local signal representation is achievable by using appropriate windowing functions within the local sampling windows where such windowing functions approximately compensate for truncation errors arising in finite representations of the exact signal. Other embodiments include windowing functions approximately compensating for the expected noise values that tend to corrupt the signal. Improved accuracy in local signal representations employing chromatic derivatives are described.

### CROSS-REFERENCE TO RELATED APPLICATIONS

The present application is a continuation-in-part of application Ser. No. 09/614,886 filed Jul. 9, 2000 and claims the benefit thereof pursuant to 35 U.S. C. § 120.

### BACKGROUND

1. Field of the Invention

The present invention relates to the general field of signal processing and, more particularly, to improving the accuracy of local signal representations based upon chromatic derivatives.

2. Description of Related Art

The modem information economy is founded upon the representation of information in the form of signals. “Signal” denotes a physical quantity that varies in space (e.g. the spatially-varying optical properties of a photograph), varies in time (e.g. time-variations of voltage levels on a wire), or varies in both space and time (e.g. a video display). “Signal processing” relates to detecting, manipulating, storing, communicating and/or extracting information from the varying physical quantities making up a signal. Important practical examples include techniques for accurate communication of voice, video or other data over imperfect communications channels, accurate storage and retrieval of data in the presence of noise, extraction of medical information from electronic or other signals probing the patient's body such as MRI, CT among others, and extraction of information from radar, sonar or seismic signals, to name just a few.

While it is common to consider signal processing in terms of electronic signals, the present invention is not limited to electronic or to any particular physical embodiment of signal. For economy of language, we describe the present invention in connection with the important practical example of processing electronic signals, understanding thereby that other physical forms of signal are included.

Conventional signal processing is typically based upon harmonic analysis in which signal behavior is approximately represented by a finite sequence of trigonometric (harmonic) functions. Local time variations of the signal are typically not well represented by such sequences of harmonic functions as trigonometric functions (as well as other classes of periodic functions) tend to be better suited for global representations of the signal over longer time intervals. While representation of a signal by a sufficiently large number of harmonic functions is theoretically capable of giving an arbitrarily accurate representation of the local behavior of a signal, global representations typically require an impractically large signal sample and impractically large number of functions to adequately represent local signal behavior. Thus, there is a need for signal processing techniques that characterize the local behavior of a signal in terms of a set of “local signal parameters” or “local signal behavior parameters” that relate the local signal behavior to the signal's spectrum, e.g. to the signal's global behavior. Such local signal processing techniques should provide a computationally effective way of rapidly monitoring a signal's instantaneous changes while maintaining spectral accuracy.

Conventional methods for representing local signal behavior, such as a Taylor series expansion, typically make use of the derivatives of the signal f(t) evaluated at a particular point to, as a component of the expansion coefficients for the signal. That is values of f(t₀), f′(t₀), f″(t₀), f′″(t₀) . . . f^{[n]} (t₀) . . . , are required in order to evaluate the Taylor series expansion of f(t) about the point t₀. In such cases, the signal is represented as an expansion in a set of basis functions (polynomial basis functions for the case of a Taylor series expansion) with derivatives appearing in the expansion coefficients (typically along with other factors). However, it is difficult to obtain accurate numerical values for the derivatives of a signal, particularly higher order derivatives as would be needed in an accurate series expansion of the signal behavior in the neighborhood of a point. Slight inaccuracies in the numerical values of the derivatives of f(t) at t₀ rapidly lead to large errors in the series expansion of f(t), becoming increasingly less accurate as a representation of the signal for points increasingly distant from to. The problems of obtaining accurate numerical values for the derivatives of a signal tend to be exacerbated in the presence of noise.

Previous work has introduced the concept of “chromatic derivatives” as mathematical operators operating on a function whereby parameters representing the local behavior of the function can be acquired or computed without encountering the inaccuracies that typically occur in conventional procedures for local signal representations. See Ignjatovic, U.S. Pat. No. 6,115,726 (hereinafter “'726 ”), the contents of which is incorporated herein by reference. Chromatic derivatives represent a unification of Nyquest's theorem (related to harmonic analysis) and Taylor's theorem related to local signal behavior, making use of polynomial approximations derived from linear operators (e.g. differential and integral operators) operating on the signal f(t). Improvements, extensions and modifications of chromatic derivatives are described by Ignjatovic and Carlin in “A New Method and a System of Acquiring Local Signal Behavior Parameters for Representing and Processing a Signal,” (U.S. Patent Application Ser. No. 09/614,886, deriving from US Provisional Patent Application Ser. No. 60/143,074 and denoted hereinafter as “'886 ”), the contents of which is incorporated herein by reference.

Chromatic derivatives have been shown to provide useful local signal representations and to facilitate a variety of signal processing procedures, as described in the above references. Thus, improving chromatic derivative technology is a useful objective of the present invention. In particular, the present invention relates to techniques for improving the representation of local signal behavior by means of chromatic derivatives.

### SUMMARY

The present invention relates generally to systems and methods for processing signals based upon the use of parameters representing the behavior of the signal over relatively limited periods of time (“local signal behavior”), in particular, to the use of chromatic derivatives. Truncation of the local signal representation with a finite number of local signal behavior parameters introduces truncation error in addition to signal-corrupting noise present in all practical signal processing systems. The present invention relates to the use of window functions that approximately compensate for truncation error and noise, improving thereby the representation of a signal over each sampling window by a finite series of local signal behavior parameters. Use of a weighted least squares fitting procedure is advantageous in extracting local signal behavior parameters where the weighting function (or the “window function”) is chosen to approximately compensate for truncation errors. In other embodiments, the window function can include the effects of noise. The window function need not be symmetric about the center of the interval and need not be linear. Various curved window functions can also be employed with good results.

Use of the techniques of the various embodiments of the present invention results in improved accuracy in digitizing analog signals, in waveform representation and in data acquisition. Improved accuracy in analog-to-digital converters and signal processing also results.

### BRIEF DESCRIPTION OF THE DRAWINGS

FIG. 1: Typical window function pursuant to some embodiments of the present invention depicted over a single sampling interval.

FIG. 2A and 2B: Typical window function pursuant to some embodiments of the present invention depicted over a single sampling interval. 2A depicts the windowing function on a linear scale and 2B is expressed in decibels.

### DETAILED DESCRIPTION

The present invention relates generally to systems and methods for processing signals (typically electronic signals) based upon the use of parameters representing the behavior of the signal over relatively limited periods of time (“local signal behavior”), in particular, to the use of chromatic derivatives. Some of the motivations for using chromatic derivatives (“CDs”) in signal processing, and some of the advantages derived from such usage, are discussed at length in '726 and '886. We give a summary of CD's here in order to fix notation and to summarize the basic concepts.

CDs are a set of linear differential operators applied to a signal function f(t), and related to the derivatives of f(t). One form of CDs (i.e., those based upon Chebyshev T polynomials) are defined recursively as follows:

$${CD}_{0} ( t ) = f ( t ) \qquad \text{Eq. 1a}$$

$${CD}_{1} f ( t ) = ( 1 / π ) {f}^{′} ( t ) \qquad \text{Eq. 1b}$$

$${CD}_{n + 1} f ( t ) = {( 2 / π ) [ {CD}_{n} f ( t ) ]}^{′} + {CD}_{n - 1} f ( t ) for n \geq 1. \qquad \text{Eq. 1c}$$

Thus, knowledge of CD₀, CD₁, . . . CDₙ, . . . CD_{M} is equivalent to knowledge of f(t) and knowledge of the first M derivatives of f(t). However, acquiring or computing CDs directly from the recursion relations of Eq. 1 confronts once again the problems associated with differentiating the signal f(t). As shown in '726 and '886, alternative methods exist for acquiring or computing the CDs that by-pass, ameliorate or eliminate the problems typically encountered in local signal representation methods involving signal derivatives. For economy of language, we denote by “chromatic differentiation” any method or any combination of methods for acquiring chromatic derivatives, whether or not actual numerical or analytic differentiation of f(t) is performed.

The transform H(ω) of a band-limited signal, f(t), having its frequency range scaled to the open interval (−π, π) is defined by Eq. 2

$$f ( t ) = ( 1 / 2 π ) {{\int }_{- π}}^{π} H ( ω ) {e}^{i ω t} ⅆ ω . \qquad Eq . 2$$

It can be shown (see '726) that an equivalent expression to the recursion relations of Eq. 1 for the n'th chromatic derivative of the function f(t) is given by Eq. 3.

$${CD}_{n} f ( t ) = ( 1 / 2 π ) {{\int }_{- π}}^{π} {i}^{n} H ( ω ) {T}_{n} ( ω / π ) {e}^{i ω t} ⅆ ω . \qquad Eq . 3$$

where Tₙ(x) is the n'th Chebyshev Polynomial of the First Kind in the variable x, denoted in brief as “Chebyshev T”. Thus, the chromatic derivatives defined by Eqs. 1, 2 and 3 are more precisely described as chromatic derivatives based upon Chebyshev T polynomials or CD [T]. Some properties and uses of CD[T]'s are given in '726.

Chromatic derivatives are not limited to CD[T]'s. Eq. 1, 2 and 3 can be modified so as to make use of other functions as described in '886. Examples of such other functions include, but are not limited to, Chebyshev polynomials Uₙ(x), Legendre polynomials Ultraspherical polynomials, among others. The properties of these polynomials are well-known in mathematics and given in numerous standard references including “Orthogonal Polynomials” by Urs. W. Hochstrasser appearing as Chapter 22 in Handbook of Mathematical Functions with Formulas, Graphs, and Mathematical Tables, Eds. M. Abramowitz and I. A. Stegun (Dover Publications, 9^{th} Printing, December 1972), pp. 771-802, the contents of which is incorporated herein by reference.

Letting f(t) represent an arbitrary π band limited signal, the n'th chromatic derivative of f(t) evaluated at a particular value t=t₀ is a number that we denote by CDₙ[f](t₀). Thus, f(t) can be expanded around the point t=t₀ by Eq. 4.

$$f ( t ) = {\sum }_{n = 0}^{∞} 2 π {a}_{n} \{ {CD}_{n} [ f ] ( {t}_{0} ) \} {B}_{n} ( t - {t}_{0} ) \qquad Eq . 4$$

Techniques for evaluating chromatic derivatives at a particular point t₀, that is, CDₙ[f](t₀), have been described in '726 and '886. As noted above, any procedure for obtaining CDₙ[f](t₀), we denote as “chromatic differentiation,” indicating thereby that CDₙ[f](t₀) carries information related to values of f(t), f′(t), f″(t), f′″(t) . . . f^{[n]} (t) . . . , evaluated at t=t₀, however acquired. The parameters aₙ depend upon the particular function upon which the definition of chromatic derivative has been based (and upon the choice of expansion basis functions Bₙ(t−t₀) in Eq. 4). One particular example is the chromatic derivatives defined in Eqs. 1, 2 and 3 based upon Chebyshev T polynomials. One convenient choice for the Bₙ basis functions in Eq. 4 are the Bessel Functions of the First Kind Jₙ (with a scale factor). That is, we may select

$${B}_{n} ( t ) = ( π / 2 ) {J}_{n} ( π t ) , \qquad Eq . 5$$

in which case it is straight forward to show that the an's in Eq. 4 are given by Eqs. 6.

$${a}_{0} = {π}^{- 2} \qquad \text{Eq. 6a}$$

$${a}_{n} = 2 {π}^{- 2} for n \geq 1. \qquad \text{Eq. 6b}$$

Thus, for CD's based upon Chebyshev T's, and the expansion basis functions Bₙ proportional to Bessel Functions of the First Kind according to Eq. 5, we have the expansion of Eq. 3 reducing to

$$f ( t ) = \{ {CD}_{0} [ f ] ( {t}_{0} ) \} {J}_{0} ( π ( t - {t}_{0} ) ) + 2 {\sum }_{n = 1}^{∞} \{ {CD}_{n} [ f ] ( {t}_{0} ) \} {J}_{n} ( π ( t - {t}_{0} ) ) \qquad Eq . 7$$

The infinite series of Eq. 4 can be approximated by M+1 terms as follows:

$$APP [ M , f ] ( t ) = {\sum }_{n = 0}^{M} 2 π {a}_{n} \{ {CD}_{n} [ f ] ( {t}_{0} ) \} {B}_{n} ( t - {t}_{0} ) \qquad Eq . 8$$

Similarly, the series of Eq. 7 becomes, in the approximation of truncating series Eq. 4 at n=M,

$$APP [ M , f ] ( t ) = \{ {CD}_{0} [ f ] ( {t}_{0} ) \} {J}_{0} ( π ( t - {t}_{0} ) ) + 2 {\sum }_{n = 1}^{M} \{ {CD}_{n} [ f ] ( {t}_{0} ) \} {J}_{n} ( π ( t - {t}_{0} ) ) . \qquad Eq . 9$$

Eq. 1, 2 and 3 represent one procedure for evaluating the numerical values of chromatic derivatives. Having knowledge of the numerical values the values of the CDs and basis functions Bₙ allows Eq. 4 to be used to represent f(t). The truncated expansion, Eq. 8, provides an approximation to the function f(t) in a neighborhood of t=t₀. The closer t is to t₀, the better approximation Eq. 8 becomes for a fixed M. Conversely, as M increases, the better the approximation of Eq. 8 becomes for a fixed t. The coefficients aₙ depend on the CDs and on the particular choice of basis functions Bₙ.

Truncating the series expansion of Eq. 4 after a finite number of terms (“n”) introduces truncation error E(n) that is defined by Eq. 10.

$$E ( n ) ≡ \vert f ( t ) - {\sum }_{k = 0}^{n} \{ {CD}_{k} [ f ] ( {t}_{0} ) \} {B}_{k} ( t - {t}_{0} ) \vert . \qquad Eq . 10$$

in which all coefficients have been incorporated into the definition of CD. E(n) of Eq. 10 has an upper bound given by the following expression, when the basis functions are based on Bessel J functions as in Eq. 5.

$$E ( n ) \leq A \sqrt{\{ 1 - {{J}_{0} [ π ( t - {t}_{0} ) ]}^{2} - 2 {\sum }_{k = 1}^{n} {{J}_{k} [ π ( t - {t}_{0} ) ]}^{2} \}} \qquad Eq . 11$$

where A in Eq. 11 is a constant which depends on the energy of the signal. The derivation of the bound of Eq. 11(and determination of A) are presented in '886. Bounds for other families of CDs can be derived in a similar way.

An alternative method of representing f(t) in a neighborhood of t₀ can be used if f(t) is known at a discrete set of points tᵢ, i=0,1,2,3, . . . K by fitting the expansion coefficients to the known values of f(tᵢ). That is, truncating Eq. 4 and incorporating coefficients in the CD's yields Eq. 12.

$$f ( t ) ≅ {\sum }_{k = 0}^{n} \{ {CD}_{k} [ f ] ( {t}_{0} ) \} {B}_{k} ( t - {t}_{0} ) = {\sum }_{k = 0}^{n} {Q}_{k} {B}_{k} ( t - {t}_{0} ) \qquad Eq . 12$$

The (n+1) coefficients Qₖ, k=0, 1, . . . n, can be determined by least-squares or other curve-fitting procedure applied to Eq. 12 at the points tᵢ for which f(tᵢ) is known.

The n+1 CD's in the truncated series of Eq. 12 are denoted as “active chromatic derivatives.” For a general input signal f(t), a large number of derivatives (or, equivalently, chromatic derivatives) can be non-zero. Derivatives may decrease slowly with higher order so the truncation of Eq. 12 may introduce non-trivial errors. The present invention relates to techniques for improving the accuracy in the signal representation by the truncated series Eq. 12 including only active chromatic derivatives.

Least squares fitting is one procedure that can be employed in conjunction with Eq. 12 to acquire the active CDs. As a least squares fit to local signal information around the point t₀, the approximation by active chromatic derivatives is better near the center of the time interval (t=t₀) than further away from the center, near the edges of the sampling interval. Thus, use of a weighted least squares fitting procedure is advantageous where the weighting function (or the “window function”) is chosen to approximately compensate for the truncation errors of Eq. 12 as known (or approximated) from the error bound of Eq. 11. Weighted least squares fitting procedures are described in standard references including Analysis of Numerical Methods, E. Isaacson and H. B. Keller (Dover Publications, 1994), pages 202-203, incorporated herein by reference.

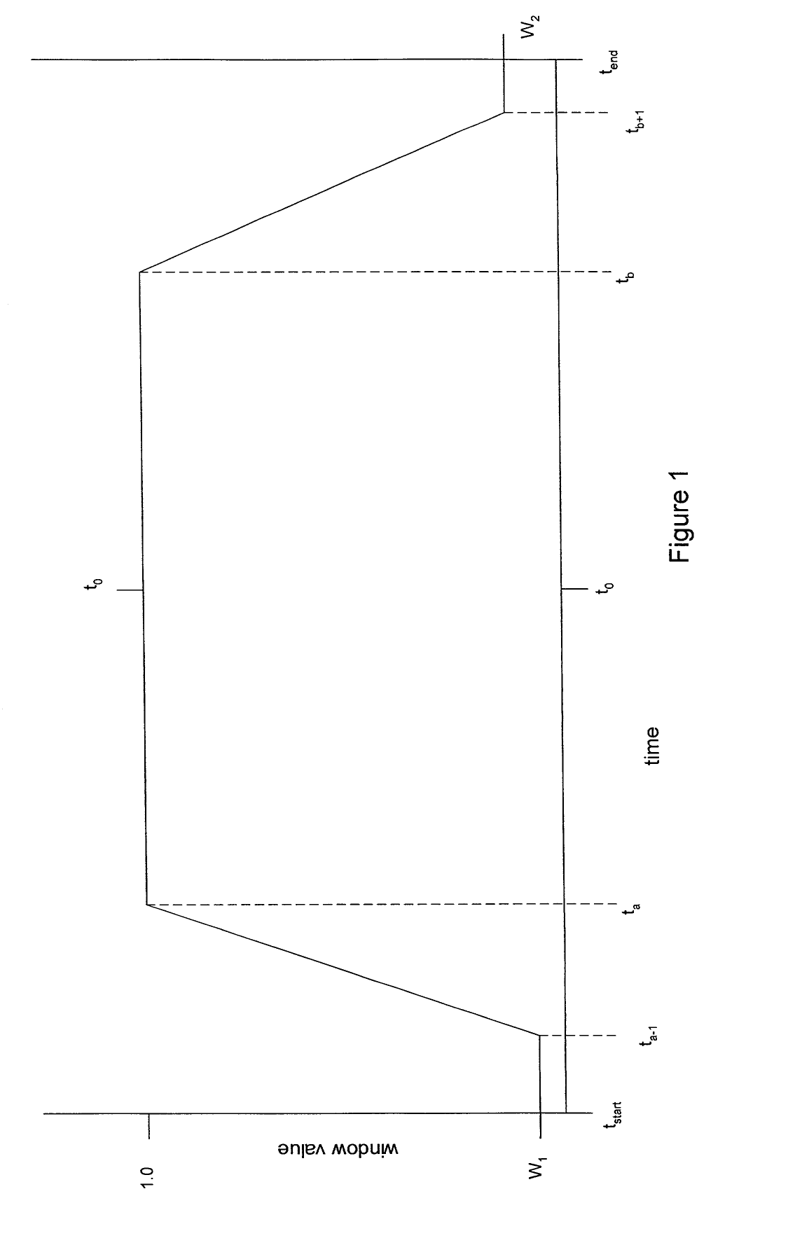

A particular example of a window function is given in FIG. 1. One typical property of window functions is illustrated in FIG. 1, namely that points away from the center of the interval typically have decreasing weight in the windowing function. General expansions of a function in a finite series of polynomials are commonly most accurate in representing the function at or near the point of expansion, to. Thus, window functions typically display their maximum values in the neighborhood of to. We depict the maximum value of the window function as 1.0 herein but this is a matter of convenience. Other choices for the absolute scale of window function can be used and will change the normalization of the fitting procedure, easily accounted for by adjustment of constants appearing in the expansion.

FIG. 1 depicts one illustrative case of a window function imposing a linear weighting away from t₀. FIG. 1 depicts a single sampling interval or sampling window. Typically, sampling a signal involves sampling over numerous sampling windows spanning the signal. In general, the interval over which the signal is to be approximated [tₛₜₐᵣₜ, t_{end}] may be varied, and need not be constant throughout a sampling and fitting procedure.

The slope, starting and finishing points of the decreasing portions of the window functions can be adjusted for optimal performance and need not be symmetrically disposed about to (although in most practical instances the window function is symmetric about the center of the sampling interval). For example, the start of the up-slope, tₐ₋₁, can coincide with the start of the sampling interval, tₛₜₐᵣₜ but need not. FIG. 1 depicts a constant weighting function for a segment of the sampling interval from tₛₜₐᵣₜ to tₐ₋₁ having a value W₁. Both W₁ and tₐ₋₁ are variable and include the particular cases of W₁=0 and/or tₐ₋₁=tₛₜₐᵣₜ.

The constant portion of the weighting function along the interval [tₐ, t_{b}] can vary in length and need not be symmetric about t₀. The particular case is also included in which

tₛₜₐᵣₜ=tₐ₋₁=tₐ and t_{b}=t_{b+1}=t_{end}, that is, a constant windowing function. A constant windowing function would be appropriate (among other cases) for the example in which the signal to be represented is known to be precisely determined by a finite series of basis functions. For example, the signal that is to be represented may have been previously constructed by an expansion of the form of Eq. 12 so the finite expansion having the same number of terms is known to be precisely correct. Other forms of window function make use of the decreased weighting away from to approximately to compensate for truncation errors and/or noise introduced into the signal.

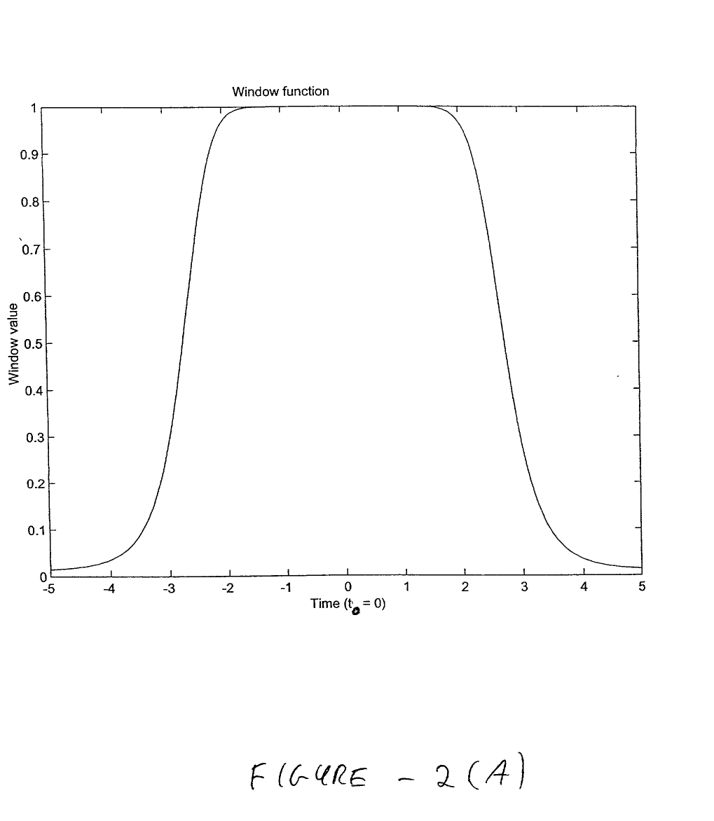

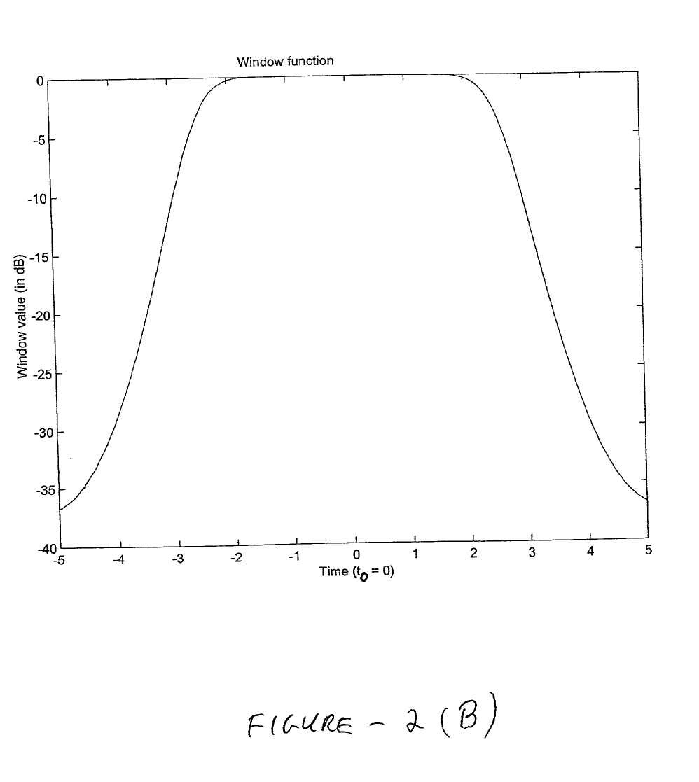

Window functions are not limited to linear weights as depicted in FIG. 1 but can include curved weightings as depicted in FIG. 2A (linear scale) and in FIG. 2B (weight scale in decibels—dB). For signals of practical interest, the weight function should be close to 1.0 in a region around the to and decrease with distance away from t₀. Within these constraints, a wide range of families of weight functions are included.

In other embodiments of the present invention, the window function can include the effects of noise. That is, in practical signal processing environments, a finite term representation of a signal such as Eq. 12 deviates from the exact signal by the presence of noise as well as by truncation error. Thus, we can depict the total error E_{Total} as the truncation error of Eq. 12 and a noise term as

$${E}_{Total} ≅ E ( n ) + E ( noise ) . \qquad Eq . 13$$

The expected noise is typically independent of time and depends on the characteristics of the transmission channel (for data transmission) or of the storage medium (for data storage). Other window functions pursuant to some embodiments of the present invention are weighted by the sum of truncation error and expected noise as in Eq. 13.

While the error bound of Eq. 10 can provide guidance as to the appropriate weighting, the behavior of the error bound with t does not necessarily follow the behavior of the error with t. Thus, the weighted fitting procedure is part mathematical (Eq. 10) and part empirical.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

We claim:

1. A method for digitizing a section of a band-limited analog signal within a sampling window comprising:
a) representing said section as a truncated series of basis functions at a sampling moment disposed approximately in said sampling window, wherein said truncated series has variable local signal behavior parameters as coefficients of said basis functions, and wherein said truncated series has a truncation error associated therewith, said truncation error tending to zero as said truncated series includes increasing numbers of basis functions; and,
b) obtaining discrete signal samples by sampling said signal within an interval disposed within said sampling window; and,
c) fitting said truncated series to said discrete signal samples, obtaining thereby numerical values for said local signal behavior parameters, whereby said fitting includes using a window function within said sampling window, wherein said window function has a form so as to partially compensate for said truncation error.

2. A method as in claim 1 wherein said local signal behavior parameters comprise chromatic derivatives.

3. A method as in claim 2 wherein said window function further has a form so as to partially compensate for noise.

4. A method as in claim 3 wherein said fitting is a weighted least squares fitting.

5. A method as in claim 2 wherein said window function is a constant.

6. An analog-to-digital converter wherein said converter has a data acquisition unit and said data acquisition unit is adapted for digitizing a section of a band-limited analog signal within a sampling window, said digitizing comprising:
a) representing said section as a truncated series of basis functions at a sampling moment disposed approximately in said sampling window, wherein said truncated series has variable local signal behavior parameters as coefficients of said basis functions, and wherein said truncated series has a truncation error associated therewith, said truncation error tending to zero as said truncated series includes increasing numbers of basis functions; and,
b) obtaining discrete signal samples by sampling said signal within an interval disposed within said sampling window; and,
c) fitting said truncated series to said discrete signal samples, obtaining thereby numerical values for said local signal behavior parameters, whereby said fitting includes using a window function within said sampling window, wherein said window function has a form so as to partially compensate for said truncation error.

7. A converter as in claim 6 wherein said local signal behavior parameters comprise chromatic derivatives.

8. A converter as in claim 7 wherein said window function further has a form so as to partially compensate for noise.

9. A converter as in claim 8 wherein said fitting is a weighted least squares fitting.

10. A converter as in claim 7 wherein said window function is a constant.

11. A signal processing system wherein said signal processing system has a data acquisition unit and said data acquisition unit is adapted for digitizing a section of a band-limited analog signal within a sampling window, said digitizing comprising:
a) representing said section as a truncated series of basis functions at a sampling moment disposed approximately in said sampling window, wherein said truncated series has variable local signal behavior parameters as coefficients of said basis functions, and wherein said truncated series has a truncation error associated therewith, said truncation error tending to zero as said truncated series includes increasing numbers of basis functions; and,
b) obtaining discrete signal samples by sampling said signal within an interval disposed within said sampling window; and,
c) fitting said truncated series to said discrete signal samples, obtaining thereby numerical values for said local signal behavior parameters, whereby said fitting includes using a window function within said sampling window, wherein said window function has a form so as to partially compensate for said truncation error.

12. A system as in claim 11 wherein said local signal behavior parameters comprise chromatic derivatives.

13. A system as in claim 12 wherein said window function further has a form so as to partially compensate for noise.

14. A system as in claim 13 wherein said fitting is a weighted least squares fitting.

15. A system as in claim 12 wherein said window function is constant.

16. A data acquisition system wherein said data acquisition system has a data acquisition unit and said data acquisition unit is adapted for digitizing a section of a band-limited analog signal within a sampling window, said digitizing comprising:
a) representing said section as a truncated series of basis functions at a sampling moment disposed approximately in said sampling window, wherein said truncated series has variable local signal behavior parameters as coefficients of said basis functions, and wherein said truncated series has a truncation error associated therewith, said truncation error tending to zero as said truncated series includes increasing numbers of basis functions; and,
b) obtaining discrete signal samples by sampling said signal within an interval disposed within said sampling window; and,
c) fitting said truncated series to said discrete signal samples, obtaining thereby numerical values for said local signal behavior parameters, whereby said fitting includes using a window function within said sampling window, wherein said window function has a form so as to partially compensate for said truncation error.

17. A system as in claim 16 wherein said local signal behavior parameters comprise chromatic derivatives.

18. A system as in claim 17 wherein said window function further has a form so as to partially compensate for noise.

19. A system as in claim 18 wherein said fitting is a weighted least squares fitting.

20. A system as in claim 17 wherein said window function is a constant.

21. A data acquisition system wherein said data acquisition system has a data acquisition unit and said data acquisition unit is adapted for digitizing a section of a band-limited analog signal within a sampling window comprising:
a) means for representing said section as a truncated series of basis functions at a sampling moment disposed approximately in said sampling window, wherein said truncated series has variable local signal behavior parameters as coefficients of said basis functions, and wherein said truncated series has a truncation error associated therewith, said truncation error tending to zero as said truncated series includes increasing numbers of basis functions; and,
b) means for obtaining discrete signal samples by sampling said signal within an interval disposed within said sampling window; and,
c) means for fitting said truncated series to said discrete signal samples, obtaining thereby numerical values for said local signal behavior parameters, whereby said fitting includes using a window function within said sampling window, wherein said window function has a form so as to partially compensate for said truncation error.

22. A system as in claim 21 wherein said local signal behavior parameters comprise chromatic derivatives.

23. A digital signal produced from an analog signal according to the method of claims 1-5.
